(19) United States
(12) Patent Application Publication
(10) Pub. No.: US 2024/0194822 A1
(43) Pub. Date: Jun. 13, 2024

(54) FABRICATION METHOD FOR SMALL SIZE LIGHT EMITING DIODES ON HIGH-QUALITY EPITAXIAL CRYSTAL LAYERS

(71) Applicant: The Regents of the University of California, Oakland, CA (US)

(72) Inventors: Srinivas Gandrothula, Ibaraki (JP); Shuji Nakamura, Santa Barbara, CA (US); Steven P. DenBaars, Goleta, CA (US)

(73) Assignee: The Regents of the University of California, Oakland, CA (US)

(21) Appl. No.: 18/577,358

(22) PCT Filed: Jul. 13, 2022
(86) PCT No.: PCT/US22/36949

§ 371 Date: Jan. 8, 2024

Related U.S. Application Data
(60) Provisional application No. 63/221,071, filed on Jul. 13, 2021.

(51) Int. Cl. H01L 33/00; H01L 25/00

(52) U.S. Cl. CPC H01L 33/007; H01L 25/50; H01L 33/0093; H01L 33/0095

(57) ABSTRACT

A method for fabricating small size light emitting diodes (LEDs) on high-quality epitaxial crystal layers. III-nitride epitaxial lateral overgrowth (ELO) layers are grown on a substrate using a growth restrict mask. III-nitride device layers are grown on wings of the III-nitride ELO layers, to form island-like III-nitride semiconductor layers. The wings of the III-nitride ELO layers have at least an order of magnitude smaller defect density than the substrate, resulting in superior characteristics for the devices made thereon. Light emitting mesas are etched from the island-like III-nitride semiconductor layers, wherein each of the light emitting mesas corresponds to a device; and a device unit pattern is etched from the island-like III-nitride semiconductor layers, wherein the device unit pattern is comprised of one or more of the light emitting mesas. The device unit pattern including the island-like III-nitride semiconductor layers is then transferred to display panel or a carrier.

### CROSS REFERENCE TO RELATED APPLICATIONS

This application claims the benefit under 35 U.S.C. Section 119(e) of the following co-pending and commonly-assigned application:

U.S. Provisional Application Ser. No. 63/221,071, filed on Jul. 13, 2021, by Srinivas Gandrothula, Shuji Nakamura and Steven P. DenBaars, entitled “FABRICATION METHOD FOR SMALL SIZE LIGHT EMITING DIODES ON HIGH-QUALITY EPITAXIAL CRYSTAL LAYERS,” attomeys' docket number G&C 30794.0804USP1 (UC 2021-974-1);
which application is incorporated by reference herein.

This application is related to the following co-pending and commonly-assigned applications:
PCT International Patent Application Serial No. PCT/US21/56154, filed on Oct. 22, 2021, by Srinivas Gandrothula and Takeshi Kamikawa, entitled “SMALL SIZE LIGHT EMITING DIODES FABRICATED VIA REGROWTH,” attorney's docket no. 30794.0784WOUI (UC 2021-561-2), which application claims the benefit under 35 U.S.C. Section 119(e) of co-pending and commonly-assigned U.S. Provisional Application Ser. No. 63/104,580, filed on Oct. 23, 2020, by Srinivas Gandrothula and Takeshi Kamikawa, entitled “SMALL SIZE LIGHT EMITTING DIODES FABRICATED VIA REGROWTH,” attorneys' docket number G&C 30794.0784USP1 (UC 2020-561-1);
all of which applications are incorporated by reference herein.

### BACKGROUND OF THE INVENTION

### 1. Field of the Invention

This invention is directed to small size light emitting diodes (LEDs) fabricated on high-quality epitaxial crystal layers.

### 2. Description of the Related Art

Micro-displays based on an array of micro-sized light emitting diodes (referred to as micro-LEDs and μLEDs) are a promising technology for a wide range of applications. In these 2-dimensional arrays, each μLED works as a single pixel of a whole image. These micro-displays can be used in applications ranging from TVs, laptops, smartphones, heads-up displays (HUDs) and augmented reality/virtual reality/mixed reality (AR/VR/MR) applications.

III-nitride μLEDs have gained much attention as a replacement for organic-LEDs (OLEDs) and liquid crystal displays (LCDs) due to the III-nitride μLEDs' tunable bandgap, long life, and superior efficiency. Next-generation displays with high pixel density also demand efficient and low cost red-green-blue (RGB) pixels with lateral dimensions below 10 μm, which eliminates the use of OLEDs and LCDs.

The III-nitride material system consists of the chemical formula BᵤAlᵥGa_{w}InₓSc_{y}Y_{z}N where 0≤u≤1, 0≤v≤1, 0≤w≤1, 0≤x≤1, 0≤y≤1, 0≤z≤1, and u+v+w+x+y+z=1. The majority of research attention focuses on InGaN-based μLEDs, although there is some research on UV-A AlGaN μLEDs for display applications.

One of the most important advantages of the III-nitride material system is the emission wavelength tunability by varying the composition percentages of Indium (In) and Gallium (Ga) in the active region, since the bandgaps of GaN and InN are 3.4 eV and 0.7 eV, respectively, and the alloy of InGaN system can theoretically cover the entire visible spectrum.

Unfortunately, III-nitride μLEDs become inefficient as device dimensions shrink, due to nonradiative recombination losses at exposed surfaces. These losses originate from nonradiative surface states, such as point defects and dangling bonds for Ga atoms, which are largely introduced during plasma-based etching of the device mesa. Due to high surface-area-to-volume ratios, these effects become ever more important for III-nitride μLEDs. Analysis of external quantum efficiency (EQE) curves suggest that the Shockley-Read-Hall (SRH) recombination rate rises by over an order of magnitude when device dimensions are dropped to such small sizes. Several research groups have introduced sidewall passivation using a combination of atomic layer deposition and/or chemical treatments to recover the damage introduced during the plasma-based etching of the device mesa (Applied Physics Express, 12, 097004 (2019)).

In addition, nitride-based μLEDs, such as μLEDs with InGaN quantum wells, also suffer from a droop effect, where the internal quantum efficiency (IQE) drops as the current density increases. There are several explanations for the droop effects, such as electron overflow, Augur recombination, and defects. One possible explanation for the efficiency droop in III-nitride LEDs was given in terms of density-activated defect recombination by Harder et al (APL, 96, 221106 (2010)). Therefore, there is a need for having less or no defects on the device mesa in applications related to small size III-nitride LEDs.

Thus, there is a need in the art for improved methods of fabricating small size III-nitride LEDs with high-quality epitaxial layers. The present invention satisfies this need.

### SUMMARY OF THE INVENTION

To overcome the limitations in the prior art described above, and to overcome other limitations that will become apparent upon reading and understanding this specification, the present invention discloses a simplified solution to achieve high-quality, small-size, III-nitride LEDs.

Specifically, the present invention discloses a method for fabricating III-nitride semiconducting layer(s) on a host substrate, where the host substrate can be a homogeneous (III-nitride) or heterogeneous (foreign) substrate, including a foreign substrate with a III-nitride template deposited thereon.

The fabrication of light emitting regions and apertures is performed on wings of III-nitride layers grown by epitaxial lateral overgrowth (ELO) using a growth restrict mask, wherein the III-nitride ELO layers exhibit a good crystal quality in terms of reduced dislocation densities and stacking faults, as compared to regions that are not grown by ELO.

For example, it has been found that the ELO technique obtains good crystalline quality with reduced defects (<10⁶ cm⁻²) in the wing regions of the ELO growth. By doing so, an advantage of less leakage currents can be achieved, which is found to be detrimental in achieving brightness.

The III-nitride μLEDs are formed from a bar of island-like III-nitride semiconductor layers comprising the III-nitride ELO layers and III-nitride device layers, wherein each bar may comprise one or more than one of the III-nitride μLEDs. By doing this, nearly identical devices can be fabricated adjacent to each other in a self-assembled array, and thus, by integration, scale up can be made easier. Alternatively, the bar of the III-nitride μLEDs may be later divided into groups of devices or individual devices.

Preferably, the III-nitride μLEDs are each small-sized, having a tile dimension less than 15 μm×15 μm or less. As fabricated, the III-nitride μLEDs can be transferred from the bar onto a different carrier for further processing by means of a simple stamp, or a vacuum chuck, or glue attached a carrier plate, etc.

Moreover, each device of such a bar can be addressed separately or together with other devices, by designing a proper fabrication process. For example, one could make a common cathode or anode for a bar of devices for monolithic integration, or one could separately address each device on a bar for full color display applications. Consequently, a high yield can be obtained.

Key aspects of this invention include:
Host substrates that are III-nitride substrates or foreign substrates, such as Si, SiC, sapphire, etc., including foreign substrates with III-nitride templates deposited thereon, can be used to scale up manufacturability for industrial needs.
This method is independent of crystal orientations of the host substrate.
III-nitride ELO layers are grown using a growth restrict mask on the host substrate, wherein the III-nitride ELO layers are grown first from opening areas in the growth restrict mask and then are grown laterally on the growth restrict mask.
III-nitride device layers are grown on wings of the III-nitride ELO layers.
The wings of the III-nitride ELO layers have a better crystal quality with defect densities smaller than 10⁶/cm², even after fabricating Indium-containing quantum wells (QWs) on the wings.
Indium fluctuations in the quantum wells can be minimized due to the high crystal quality, where the minimized indium fluctuations lead to a narrow emission, which is a desirable characteristic when representing crisp colors.
Light emitting mesas and apertures are also formed on the wings of the III-nitride ELO layers.
Plasma-induced damage when defining the light emitting mesas can be kept to a minimum.
Complex damage recovery methods can be avoided.
Fewer processing steps are needed, thus simplifying fabrication and reducing production cost.
Due to reduced defect densities of the light emitting mesas, pick-and-place by elastomer stamps or other simple mechanisms can be used when transferring devices from the host substrate to an external carrier.
There are reduced crystalline defects on device layers, and therefore device transfer procedures that involve electrical equipment may not cause leakage or breakdown or damage to devices, thus increasing yields in production.
Devices can be transferred as a group or individually to the external carrier, as determined by the application.
The host substrate can be recycled for a next batch of devices.

A few of the possible designs using this method are illustrated in the following detailed description of the invention. The invention has many benefits as compared to conventionally manufacturable device elements.

### BRIEF DESCRIPTION OF THE DRAWINGS

Referring now to the drawings in which like reference numbers represent corresponding parts throughout:

FIG. 1 illustrates schematics of a substrate and a growth restrict mask, with both non-coalesced and coalesced ELO layers, according to one embodiment of the present invention.

FIG. 2A illustrates schematics of device layers on island-like III-nitride semiconductor layers when ELO layers are not-coalesced and coalesced; FIG. 2B is a magnified view of the typical device layers including flat and layer bending regions, and FIG. 2C are schematics of typical fabricated devices along the ELO wing regions on both the sides of the open region.

FIG. 3 illustrates device unit patterns and light emitting mesas for devices on the host substrate.

FIGS. 4A, 4B, 4C, 4D, and 4E illustrate a pick-and-place transfer method for devices, as well as both lateral and vertical pad configurations.

FIGS. 5A, 5B, 5C, 5D, 5E, 5F, 5G and 5H are scanning electron micrograph (SEM) and cathode luminescence (CL) images of light emitting mesas fabricated on a bulk GaN substrate and on a wing of layers grown on of the bulk GaN substrate.

FIGS. 6A, 6B. 6C and 6D are graphs of current density (A/cm²) vs. voltage (V) and relative output power (μW) vs. current density (kA/cm²) for light emitting mesas having dimensions of 10 μm×10 μm and 15 μm×15 μm fabricated on a planar bulk GaN substrate and on wing regions of ELO layers grown on the substrate.

FIGS. 6E, 6F, 60 and 6H are graphs of peak wavelength (nm) and full-width at half-maximum (FWHM) (nm) of the peak wavelength vs. current density (kA/cm²) for light emitting mesas having dimensions of 10 μm×10 μm and 15 μm×15 μm fabricated on a planar bulk GaN substrate and on wing regions of ELO layers grown on the substrate.

FIGS. 7A and 7B are schematics of lateral injection and vertical injection LEDs, FIG. 7C is a graph of current (mA) vs. voltage (V) for the lateral injection and vertical injection LEDs, and FIG. 7D is a graph of peak wavelength (nm) vs. FWHM (nm) of the peak wavelength vs. current density (kA/cm²), which was measured after separating devices from the substrate.

FIG. 8 is a flowchart illustrating a method for fabricating devices, according to this invention.

### DETAILED DESCRIPTION OF THE INVENTION

In the following description of the preferred embodiment, reference is made to a specific embodiment in which the invention may be practiced. It is to be understood that other embodiments may be utilized, and structural changes may be made without departing from the scope of the present invention.

Overview The present invention describes a method of fabricating semiconductor devices, such as light emitting devices, including LEDs, on wings of III-nitride ELO layers, which are of good crystal quality. This invention uses host (growth) substrates that may be homogeneous (III-nitride) substrates, such as GaN and AlN, or heterogeneous (foreign) substrates, such as Si, SiC, including foreign substrates with III-nitride templates deposited thereon. The LEDs, including micro-LEDs and micro-cavity LEDs, can be selectively transferred as a group or individually from the host substrate onto an external carrier, such as a display panel.

The fabrication steps are described in more detail below.

### Step 1: Forming a Growth Restrict Mask on a Substrate

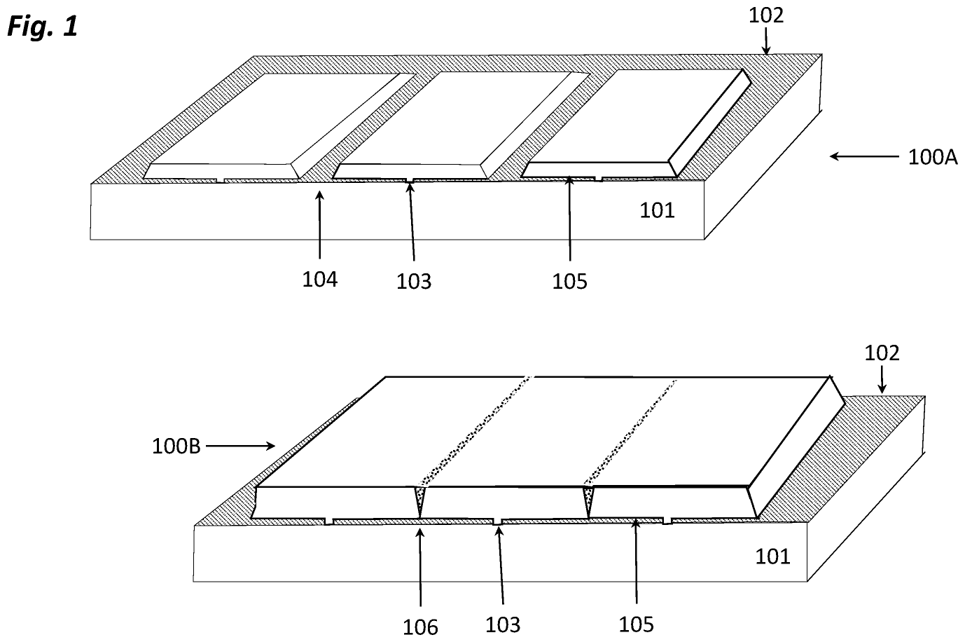

FIG. 1 illustrates Step 1 using schematics 100A and 100B, wherein the method first provides the host substrate 101.

In schematic 100A, a growth restrict mask 102 is formed on or above the III-nitride based substrate 101. Specifically, the growth restrict mask 102 is deposited directly on the substrate 101, or is deposited directly on a III-nitride template deposited on the substrate 101.

The growth restrict mask 102 can be formed from an insulator film, for example, an SiO₂ film, deposited upon the substrate 101, for example, by a plasma chemical vapor deposition (CVD), sputter, ion beam deposition (IBD), etc., wherein the SiO₂ film is patterned by photolithography using a predetermined photo mask and then etched to include opening areas 103, as well as no-growth regions 104 (which may or may not be patterned).

The present invention can also use SiN, SiON, TiN, etc., as the growth restrict mask 102. A multi-layer growth restrict mask 102 is preferred.

### Step 2: Epitaxial Growth of III-Nitride Layers

In Step 2, epitaxial growth of III-nitride layers 105, such as GaN-based layers, is performed using the ELO method on or above the substrate 101 using the growth restrict mask 102, such that the growth of the III-nitride ELO layers 105 extends in a direction parallel to the striped opening areas 103 of the growth restrict mask 102.

The growth of the III-nitride ELO layers 105 occurs first in the opening areas 103, on or above the substrate 101, and then laterally from the opening areas 103 over the growth restrict mask 102. The growth of the III-nitride ELO layers 105 may be stopped or interrupted before the III-nitride ELO layers 105 at adjacent opening areas 103 can coalesce on top of the growth restrict mask 102, wherein this interrupted growth results in the no-growth regions 104 between adjacent III-nitride ELO layers 105. Alternatively, the growth of the III-nitride ELO layers 105 may be continued and coalesce with neighboring III-nitride ELO layers 105, as shown in schematic 100B, thereby forming a coalesced region 106 of increased defects at a meeting region.

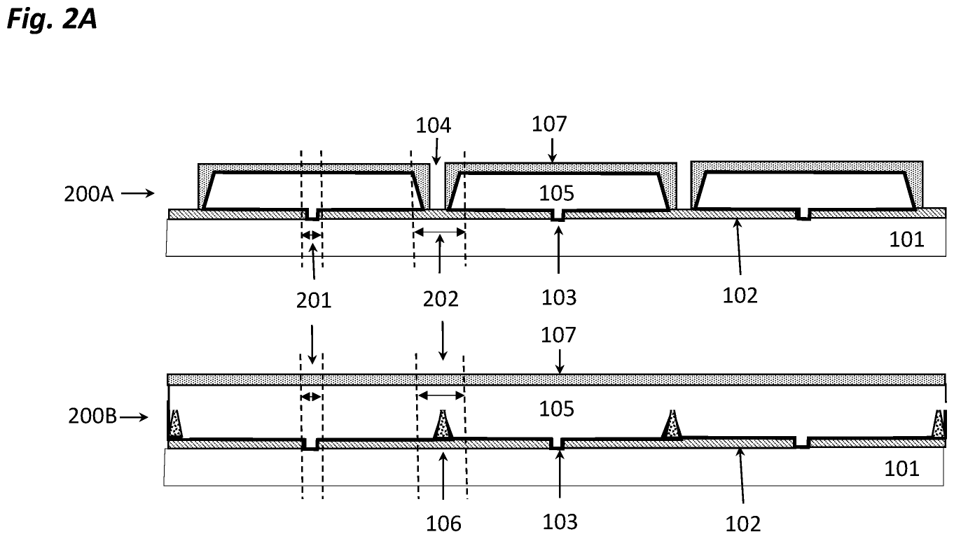

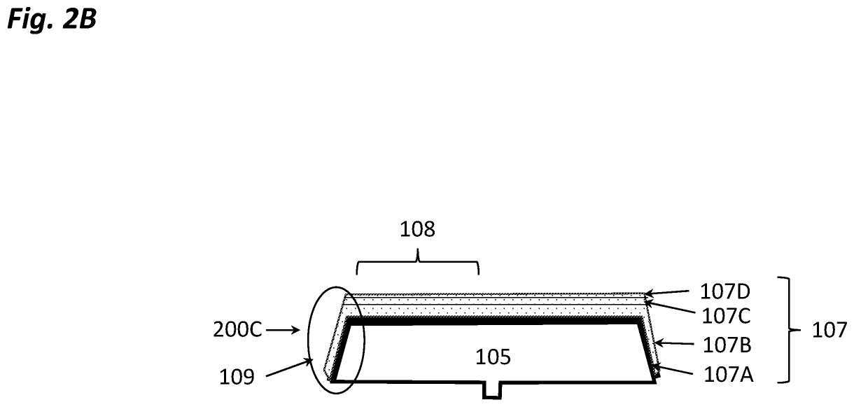

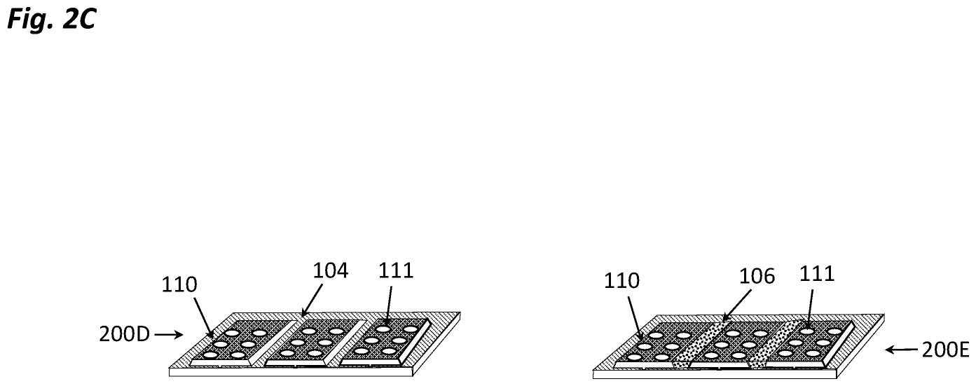

As shown in schematics 200A and 200B in FIG. 2A, additional III-nitride device layers 107 are grown on or above the III-nitride ELO layers 105. An open region of the III-nitride ELO layer 105 and additional III-nitride device layers 107 is labeled as region 201, and a region at the which neighboring III-nitride ELO layer 105 wings may or may not meet is labeled as region 202.

As shown in schematic 200C in FIG. 2B, the III-nitride ELO layers 105 include at least one n-type III-nitride ELO layer 105, and the III-nitride device layers 107 include an active region 107A, p-type layer 107B, electron blocking layer (EBL) 107C, and cladding layer 107D, as well as other layers. The III-nitride ELO layers 105 and the III-nitride device layers 107 together form island-like III-nitride semiconductor layers.

The III-nitride ELO layers 105 and III-nitride device layers 107 include one or more flat surface regions 108 and layer bending regions 109 at the edges thereof adjacent the no-growth regions 104, when the III-nitride ELO layers 105 stopped before coalescing as shown in schematic 100A, or the regions 202, when the III-nitride ELO layers 105 are continued to coalesce in a coalesced region 106 as shown in schematic 100B. The width of the flat surface region 108 is at least 3 μm, and most preferably is 10 μm or more.

The light-emitting active region 107A of the devices 110 is processed at the flat surface regions 108 on either side of the no-growth region 104 or coalesced region 202, preferably between opening area 103 and the layer bending portion 109 or coalesced region 106. By doing so, a bar of a device 110 will possess an array of nearly identical light emitting apertures 111 on either side of the opening area 103 along the length of the bar, as shown in schematics 200D and 200E in FIG. 2C.

### Step 3: Defining a Light Emitting Mesa

In Step 3, a light emitting mesa is defined on the flat surface region 108 of the wings of the island-like III-nitride semiconductor layers 105, 107 using conventional methods and exposing the underlying n-type III-nitride ELO layers 105 by plasma-based environment etching.

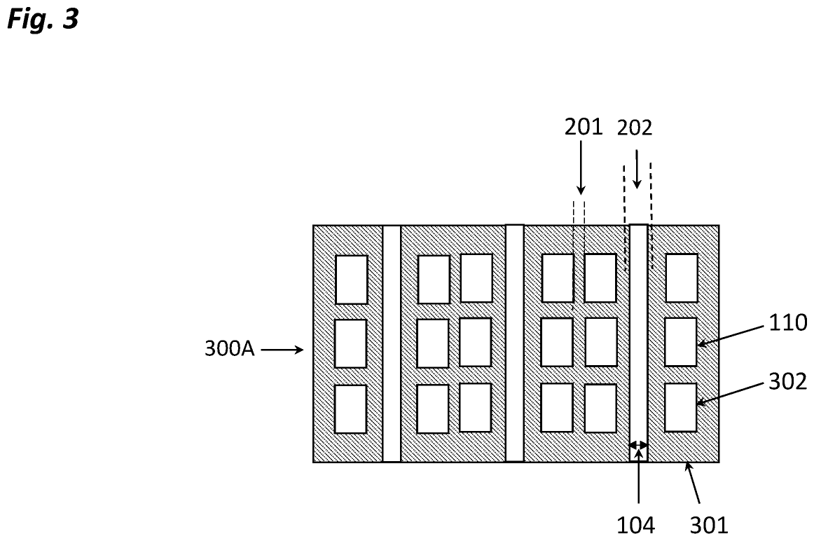

As shown in schematic 300A of FIG. 3, the island-like III-nitride semiconductor layers 105, 107 are divided at regions 202 and/or 201 into device unit patterns 301 using, for example, dry etching or laser scribing, etc., wherein the device unit patterns 301 are divided into one or more light emitting mesas 302 on the wings of the island-like III-nitride semiconductor layers 105, 107 using, for example, dry etching or laser scribing, etc., and each of the light emitting mesas 302 corresponds to a single device 110. Typically, the light emitting mesas 302 are etched first and then the device unit patterns 301 are etched, although the reverse could occur as well.

To ensure a good crystal quality for the devices 110, the device unit patterns 301 and light emitting mesas 302 are positioned away from the no-growth region 104. For example, at least a 1 μm distance from the no-growth region 104 would ensure a good crystal quality for the devices 110.

### Step 4: Deposit a Protection Layer on the Sidewalls of the Mesa

In Step 4, a protection layer, such as a passivation layer, may be placed around the sidewalls of each of the light emitting mesas 302. Before deposition of the protection layer, a chemical treatment may be used, for example, a buffered hydrofluoric acid (BHF) can be used.

As noted above, in a separation process, regions 201, 202 are etched at least to expose the growth restrict mask 102, if necessary, and the island-like III-nitride semiconductor layers 105, 107 are divided into individual devices 110 or are kept together as a group of devices 110. The island-like III-nitride semiconductor layers 105, 107 still remain on the growth restrict mask 102 of the host substrate 101 for processing, such as solvent cleaning, UV ozone exposure, etc. Therefore, cleaning the devices 110 after separation using reactive ion etching (RIE) or some other technique will help to remove residues from the processing, and may also help to prepare the surface for chemical treatments for recovering etch damage, as well as bonding processes. This is a big advantage for reducing the process time and cost. Alternatively, the protection layer may serve as an assist layer to secure the island-like III-nitride semiconductor layers 105, 107 to the host substrate 101.

Many kinds of materials can be used as the protection layer, such as SiOx, SiNx, AlOx, SiONx, AlONx, TaOx, ZrOx, AlNx, TiOx, NbOx and so on (where x>0). It is preferable that the protection layer is a transparent layer for light from the active region 107A of the device 110, because then there is no need to remove the protection layer after removing the island-like III-nitride semiconductor layers 105, 107 from the substrate 101.

Alternatively, the protection layer may be an insulation layer. If the protection layer is not an insulation layer, the protection layer connects both the n-type III-nitride ELO layer 105 and the p-type III-nitride device layer 107B, which eventually would result in a short current, in which case, the protection layer has to be removed. Thus, the protection layer should be transparent and an insulation layer.

Moreover, AlONx, AlNx, AlOx, SiOx, SiN, SiON can passivate the device 110 surface, especially an etched GaN crystal. Since the protection layer covers the sidewalls of the device 110, choosing these materials is preferable to reduce current leakage which flows from the sidewalls of the device 110. Moreover, the smaller the size of the device 110, the more the current leakage. Passivating the sidewalls of the device 110 is very important.

### Step 5: Deposit Contacts

In Step 5, electrical contacts are deposited on the n-type III-nitride ELO layer 105 and p-type III-nitride device layer 107B for electrical injection, following the etching of the device unit patterns 301 and the light emitting mesas 302.

In a lateral pad configuration for the devices 110, the n-type III-nitride ELO layer 105 is exposed by the plasma etching of the light emitting mesas 302, using silicon-tetra-chloride (SiCl₄) or chlorine (Cl₂) gas, followed by the deposition of an n-contact.

In a vertical lateral pad configuration for the devices 110, the back surface of the n-type III-nitride ELO layer 105 is used for an n-contact, after lifting off the island-like III-nitride semiconductor layers 105, 107 from the host substrate 101.

Step 6: Pick the Devices from the Substrate

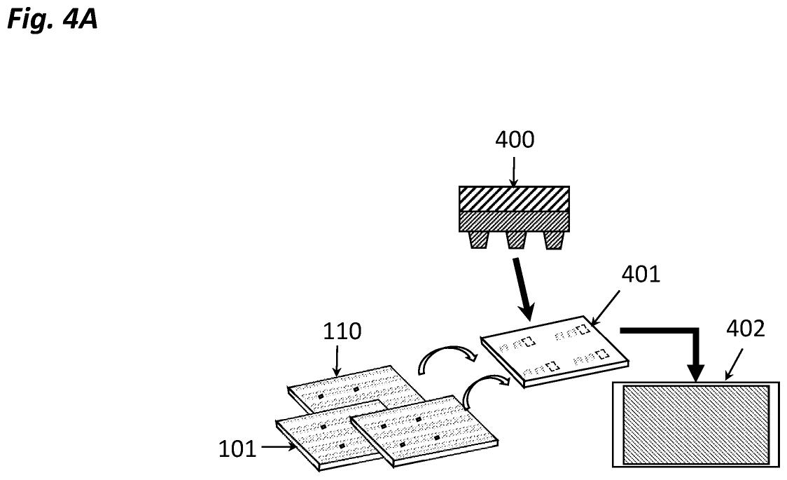

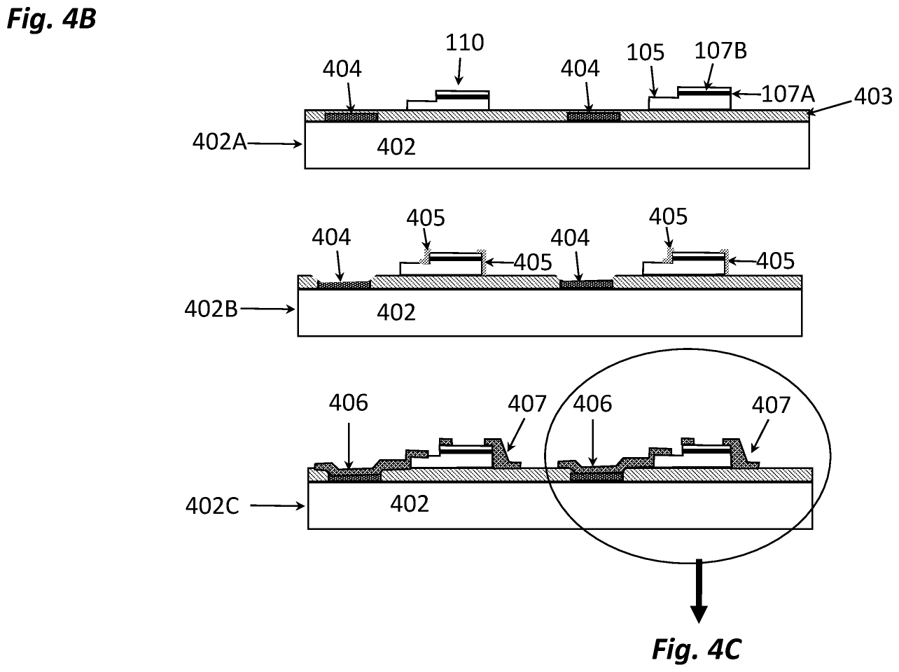

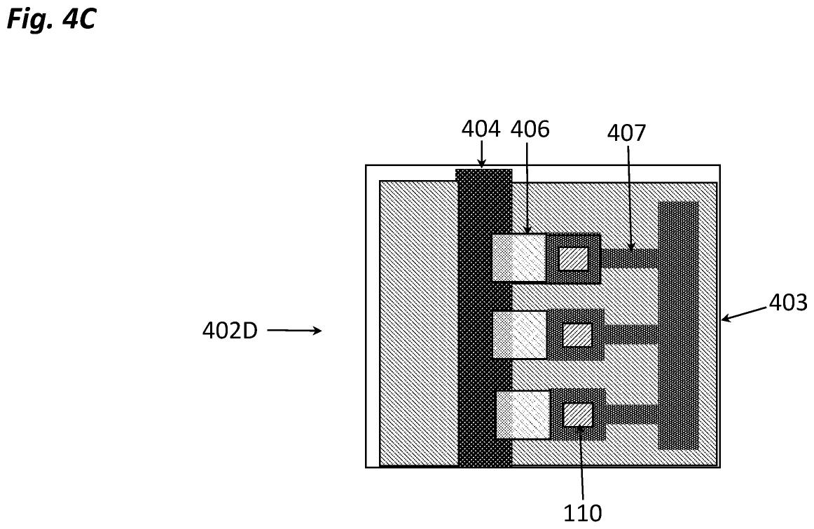

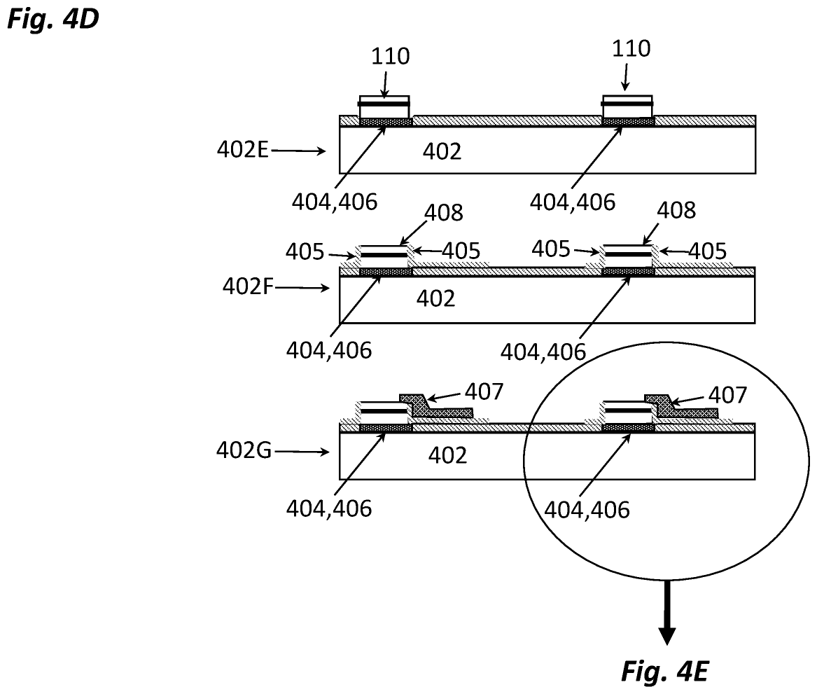

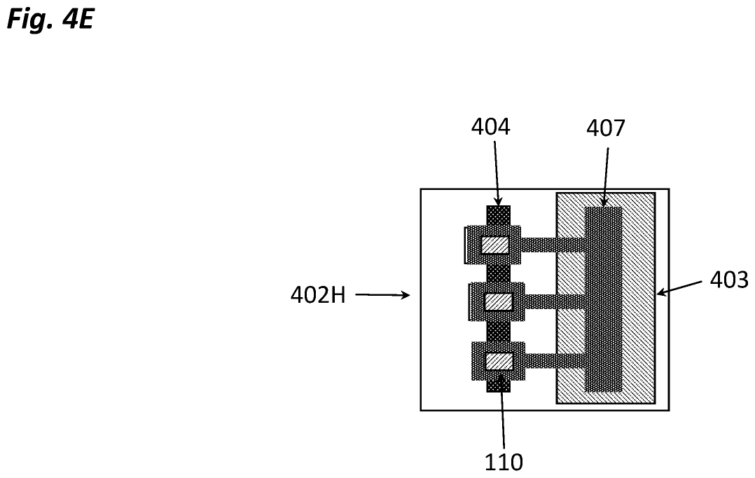

In Step 6, as shown in FIG. 4A, the completed devices 110 are picked from the host substrates 101 by an elastomer (PDMS) stamp 400, vacuum chuck, etc. The stamps 400 are flexible enough to selectively pick individual III-nitride devices 110 from the host substrate 101, or to selectively pick groups of III-nitride devices 110 from the host substrate 101.

### Step 7: Place the Picked Devices on an Imposer and Disperse to a Display Panel

In Step 7, as shown in FIG. 4A, the picked devices 110 are placed on an intermediate imposer 401 and then the devices 110 are dispersed from the imposer 401 onto a display panel 402 or other external carrier. The display panel 402 can be used in various applications, such as TVs, laptops, phones, AR/VR/MR, HUDs, retina display applications, etc.

As shown in the cross-sectional side-view schematic 402A in FIG. 4B, the display panel 402 has an upper layer that is an insulator or separator 403, upon which the device 110 is placed.

As shown in the cross-sectional side-view schematic 402B in FIG. 4B, the insulator or separator 403 covering the is etched or removed from an embedded electrode track 404, which is used for n-type electrical connection to the device 110. A protective layer 405 is deposited over the sidewalls of the device 110 to isolate electrical pads.

As shown in the cross-sectional side-view schematic 402C in FIG. 4B, an n-contact 406 and p-contact 407 are then deposited for electrical connection to the device 110. The portion of schematic 402C that is circled is further illustrated in FIG. 4C.

The top-view schematic 402D in FIG. 4C, shows the insulator or separator 403, embedded electrode track 404, n-contact 406 and p-contact 407 in a lateral pad configuration for the devices 110.

As shown in the cross-sectional side-view schematic 402E in FIG. 4D, the display panel 402 has an upper layer that is an insulator or separator 403, upon which the device 110 is placed, which is etched or removed from an embedded electrode track 404 used for n-type electrical connection to the device 110. The devices 110 are then placed on the embedded electrode track 404, wherein the n-contact 406 on a backside of the n-type III-nitride ELO layer 105 contacts the embedded electrode track 404 for the n-type electrical connection.

As shown in the cross-sectional side-view schematic 402F in FIG. 4D, a protective layer 405 is deposited on the sidewalls of the devices 110 and a current spreading layer 408, such as ITO, is deposited on the devices 110.

As shown in the cross-sectional side-view schematic 402G in FIG. 4D, a p-contact 407 is then deposited for electrical connection to the current spreading layer 408. The portion of schematic 402G that is circled is further illustrated in FIG. 4E.

The top-view schematic 402H in FIG. 4E, shows the insulator or separator 403, embedded electrode track 404, and p-contact 407 in a vertical pad configuration for the devices 110.

### Definitions of Terms

### III-Nitride-Based Substrate

The host substrate 101 may comprise a III-nitride-based substrate 101, which may comprise any type of III-nitride-based substrate 101, as long as a III-nitride-based substrate 101 enables growth of III-nitride-based semiconductor layers 105, 107, through a growth restrict mask 102, such as a GaN substrate 101 that is sliced on a {0001}, {11-22}, {1-100}, {20-21}, {20-2-1}, {10-11}, {10-1-1} plane, etc., or other plane, from a GaN and AlN bulk crystal.

### Hetero-Substrate

Moreover, the host substrate 101 may comprise a foreign substrate 101, such as sapphire, Si, GaAs, SiC, Ga₂O₃, etc. Moreover, a III-nitride semiconductor layer may be grown as a template on the foreign substrate 101 prior to the growth restrict mask 102. A III-nitride semiconductor layer is typically grown on the foreign substrate 101 to a thickness of about 2-6 μm, and then the growth restrict mask 102 is disposed on the III-nitride semiconductor layer.

### Growth Restrict Mask

The growth restrict mask 102 comprises a dielectric layer, such as SiO₂, SiN, SiON, Al₂O₃, AlN, AlON, MgF, ZrO₂, TiN etc., or a refractory metal or precious metal, such as W, Mo, Ta, Nb, Rh, Ir, Ru, Os, Pt, etc. The growth restrict mask 102 may be deposited by sputter, electron beam evaporation, plasma-enhanced chemical vapor deposition (PECVD), ion beam deposition (IBD), etc., but is not limited to those methods.

The growth restrict mask 102 may be a laminate structure selected from the above materials. The growth restrict mask 102 may also have a multiple-stacking layer structure chosen from the above materials.

In one embodiment, the thickness of the growth restrict mask 102 is about 0.05-3 μm. The width of the growth restrict mask 102 is preferably larger than 20 μm, and more preferably, the width is larger than 40 μm.

The growth restrict mask 102 is comprised of striped opening areas 103, wherein the stripes of the growth restrict mask 102 between the opening areas 103 have a width of 1 μm-20 μm and an interval of 10 μm-180 μm.

On an m-plane free standing GaN substrate 101, the growth restrict mask 102 has a plurality of opening areas 103, which are stripes arranged in a first direction parallel to the [11-20] direction of the substrate 101 and a second direction parallel to the [0001] direction of the substrate 101, periodically at intervals extending in the second direction.

On a c-plane free standing GaN substrate 101, the opening areas 103 are arranged in a first direction parallel to the 11-20 direction of the substrate 101 and a second direction parallel to the [1-100] direction of the substrate 101.

On a semipolar (20-21) or (20-2-1) GaN substrate 101, the opening areas 103 are arranged in a first direction parallel to [−1014] and 110-141, respectively.

The length of each opening area 103 is, for example, 200 to 35000 μm, and the width is, for example, 2 to 180 μm. The width of the opening area 103 is typically constant in the second direction, but may be changed in the second direction as necessary.

Alternatively, a hetero-substrate 101 can be used. For example, when a c-plane GaN template is grown on a c-plane sapphire substrate 101, the opening area 103 is in the same direction as a c-plane free-standing GaN substrate; when an m-plane GaN template is grown on an m-plane sapphire substrate 101, the opening area 103 is same direction as an m-plane free-standing GaN substrate. By doing this, an m-plane cleaving plane can be used for dividing the bar of the device 110 with the c-plane GaN template, and a c-plane cleaving plane can be used for dividing the bar of the device 110 with the m-plane GaN template; which is much preferable.

### III-Nitride Materials

The terms “III-nitride” or “Group-III nitride” or “nitride” or “III-N” as used herein refer to any composition or material related to (B, Al, Ga, In, Sc, Y)N semiconductors having the formula BᵤAlᵥGa_{w}InₓSc_{y}Y_{z}N where 0≤u≤1, 0≤v≤1, 0≤w≤1, 0≤x≤1, 0≤y≤1, 0≤z≤1, and u+v+w+x+v+z=1. These terms as used herein are intended to be broadly construed to include respective nitrides of the single species, B, Al, Ga, In, Sc and Yn, as well as binary, ternary and quaternary compositions of such Group Il metal species. Accordingly, these terms include, but are not limited to, the compounds of AlN, GaN, InN, AlGaN, AlInN, InGaN, AlGaInN, etc. When two or more of the (B, Al, Ga, In, Sc, Y)N component species are present, all possible compositions, including stoichiometric proportions as well as off-stoichiometric proportions (with respect to the relative mole fractions present of each of the (B, Al, Ga, In, Sc, Y)N component species that are present in the composition), can be employed within the broad scope of this invention. Further, compositions and materials within the scope of the invention may further include quantities of dopants and/or other impurity materials and/or other inclusional materials.

This invention also covers the selection of particular crystal orientations, directions, terminations and polarities of III-nitride materials. When identifying crystal orientations, directions, terminations and polarities using Miller indices, the use of braces, { }, denotes a set of symmetry-equivalent planes, which are represented by the use of parentheses, ( ). The use of brackets, [ ], denotes a direction, while the use of brackets, < >, denotes a set of symmetry-equivalent directions.

Many III-nitride devices are grown along a polar orientation, namely a c-plane {0001} of the crystal, although this results in an undesirable quantum-confined Stark effect (QCSE), due to the existence of strong piezoelectric and spontaneous polarizations. One approach to decreasing polarization effects in III-nitride devices is to grow the devices along nonpolar or semipolar orientations of the crystal.

The term “nonpolar” includes the {11-20} planes, known collectively as a-planes, and the {10-10} planes, known collectively as m-planes. Such planes contain equal numbers of Group-III and Nitrogen atoms per plane and are charge-neutral. Subsequent nonpolar layers are equivalent to one another, so the bulk crystal will not be polarized along the growth direction.

The term “semipolar” can be used to refer to any plane that cannot be classified as c-plane, a-plane, or m-plane. In crystallographic terms, a semipolar plane would be any plane that has at least two nonzero h, i, or k Miller indices and a nonzero 1 Miller index. Subsequent semipolar layers are equivalent to one another, so the crystal will have reduced polarization along the growth direction.

### Growing a Plurality of Epitaxial Layers on the Substrate Using the Growth Restrict Mask

The III-nitride semiconductor device layers 107 are grown on or above the III-nitride ELO layers 105 in the flat region 108 by conventional methods, such as MOCVD, HVPE, etc.

The III-nitride device layers 107 generally comprise more than two layers, including at least one layer among an n-type layer, an undoped layer and a p-type layer. The III-nitride device layers 107 may further comprise a GaN layer, an AlGaN layer, an AlGaInN layer, an InGaN layer, etc.

In an embodiment where the island-like III-nitride semiconductor layers 105, 107 do not coalesce, the distance between the island-like III-nitride semiconductor layers 105, 107 adjacent to each other is generally 30 μm or less, and preferably 10 μm or less, but is not limited to these values. In an embodiment where the island-like III-nitride semiconductor layers 105, 107 do coalesce, etching may be later performed to remove unwanted regions 106.

Trimethylgallium (TMGa), trimethylindium (TMIn) and triethylaluminium (TMAl) are used as III elements sources. Ammonia (NH₃) is used as the raw gas to supply nitrogen. Hydrogen (H₂) and nitrogen (N₂) are used as a carrier gas of the III elements sources. It is important to include hydrogen in the carrier gas to obtain a smooth surface epi-layer.

Saline and Bis(cyclopentadienyl)magnesium (Cp₂Mg) are typically used as n-type and p-type dopants. The pressure setting typically is 50 to 760 Torr. III-nitride-based semiconductor layers are generally grown at temperature ranges from 700 to 1250° C.

For example, the growth parameters include the following: TMG is 12 sccm, NH₃ is 8 slm, carrier gas is 3 slm, SiH₄ is 1.0 sccm, and the V/III ratio is about 7700.

### ELO of Limited Area Epitaxy (LAE) III-Nitride Layers

In the prior art, a number of pyramidal hillocks have been observed on the surface of m-plane III-nitride films following growth. See, for example, US Patent Application Publication No. 2017/0092810. Furthermore, a wavy surface and depressed portions have appeared on the growth surface, which made the surface roughness worse. This is a very severe problem. For example, according to some papers, a smooth surface can be obtained by controlling an off-angle (>1 degree) of the substrate's growth surface, as well as by using an N₂ carrier gas condition. These are very limiting conditions for mass production, however, because of the high production costs. Moreover, GaN substrates have a large fluctuation of off-angles to the origin from their fabrication methods. For example, if the substrate has a large in-plane distribution of off-angles, it has a different surface morphology at these points in the wafer. In this case, the yield is reduced by the large in-plane distribution of the off-angles. Therefore, it is necessary that the technique does not depend on the off-angle in-plane distribution.

The present invention solves these problems as set forth below:
1. The growth area is limited by the area of the growth restrict mask 102 from the edges of the substrate 101.
2. The substrate 101 is a nonpolar or semipolar III-nitride substrate 101 that has off-angle orientations ranging from −16 degrees to +30 degrees from the m-plane towards the c-plane. Alternatively, a foreign substrate 101 with a III-nitride template deposited thereon may be used, wherein the template has an off-angle orientation ranging from +16 degrees to −30 degrees from the m-plane towards the c-plane.
3. The island-like III-nitride semiconductor layers 105, 107 have a long side that is perpendicular to an a-axis of the III-nitride semiconductor crystal.
4. During MOCVD growth, a hydrogen atmosphere can be used.

In this invention, a hydrogen atmosphere can be used during non-polar and semi-polar growth. This condition is preferable because hydrogen can prevent excessive growth at the edge of the open area 103 from occurring in the initial growth phase.

Those results have been obtained by the following growth conditions.

In one embodiment, the growth pressure ranges from 60 to 760 Torr, although the growth pressure preferably ranges from 100 to 300 Torr to obtain a wide width for the island-like III-nitride semiconductor layers 105, 107; the growth temperature ranges from 900 to 1200° C. degrees; the V/III ratio ranges from 10-30,000; the TMG is from 2-20 sccm; NH₃ ranges from 0.1 to 10 slim, and the carrier gas is only hydrogen gas, or both hydrogen and nitrogen gases. To obtain a smooth surface, the growth conditions of each plane needs to be optimized by conventional methods.

After growing for about 2-8 hours, the III-nitride ELO layers 105 had a thickness of about 1-50 μm and a bar width of about 50-150 μm.

### Merits of Epitaxial Lateral Overgrowth

The crystallinity of the III-nitride ELO layers 105 grown from the opening areas 103 and then laterally on the growth restrict mask 102 is very high.

Also, as the growth restrict mask 102 and the III-nitride ELO layers 105 are not bonded chemically, the stress in the III-nitride ELO layers 105 can be relaxed by a slide caused at the interface between the growth restrict mask 102 and the III-nitride ELO layers 105.

### Flat Surface Region

The flat surface region 108 is between layer bending regions 109. Furthermore, the flat surface region 108 is in the region of the growth restrict mask 102.

Fabrication of the semiconductor device 110 is mainly performed on the flat surface region 108. The width of the flat surface region 108 is preferably at least 5 μm, and more preferably is 10 μm or more. The flat surface region 108 has a high uniformity of thickness for each of the island-like III-nitride semiconductor layers 105, 107.

### Layer Bending Region

If the layer bending region 109 that includes the active layer 107A remains in the device 110, a portion of the emitted light from the active layer 107A is reabsorbed. As a result, it is preferable to remove at least a part of the active layer 107A in the layer bending region 109 by etching.

From another point of view, an epitaxial layer of the flat surface region 108 except for the opening area 103 has a lesser defect density than an epitaxial layer of the opening area 103. Therefore, it is more preferable that aperture structures should be formed in the flat surface region 108 including on a wing of the III-nitride ELO layers 105.

### Fabricating the Device

The device 110 is fabricated at the flat surface region 108 by conventional methods, and thus various device designs are possible. For example, μLEDs may be fabricated, if only the front-end process is enough to realize device, such as p-pads and n-pads can be fabricated either along the length or width of the wings of the III-nitride ELO layers 105. Preferably, either a lateral or vertical pad configuration, as shown in FIGS. 4A-4E, is used to minimize fabrication time.

### Semiconductor Device

The semiconductor device 110 may be, for example, a light-emitting diode, a laser diode, a photodiode, a Schottky diode, a transistor, etc., but is not limited to these devices. This invention is particularly useful for micro-LEDs and laser diodes, which require smooth regions for cavity formation.

ELO III-Nitride Device Layers are Removed from the Substrate

The completed III-nitride devices 110 may be transferred from their host substrate 101 to a display panel 402 or other external carrier using various methods.

For example, as shown in FIG. 4A, elastomer (PDMS) stamps 400 are flexible enough to pick-and-place selected groups of devices 110 or individual nitride devices 110 from their host substrate 101 onto a display panel 402 or external carrier.

### ALTERNATIVE EMBODIMENTS

The following describes alternative embodiments of the present invention.

### First Embodiment

In a first embodiment, the devices 110 are μLEDs used with a display panel 402.

In this embodiment, the III-nitride ELO layers 105 are allowed to coalesce with neighboring III-nitride ELO layers 105 in order to form a foundation layer for the desired device 110. Thereafter, the III-nitride device layers 107 are grown on or above the III-nitride ELO layers 105 on wings of the III-nitride ELO layers 105. Light emitting mesas 302 are formed by exposing the III-nitride ELO layers 105 and III-nitride device layers 107 to a plasma etching environment, wherein the light emitting mesas 302 are dimensioned from 10 μm×10 μm to 15 μm×15 μm. A transparent conducting layer (TCO), such as indium tin oxide (ITO), is deposited on top of the light emitting mesa 302.

For the sake of demonstration, the semi-polar (20-2-1) crystal plane of a bulk Gan substrate 101 was chosen as the growth surface. Alternatively, any crystal plane of the III-nitride crystal may be used.

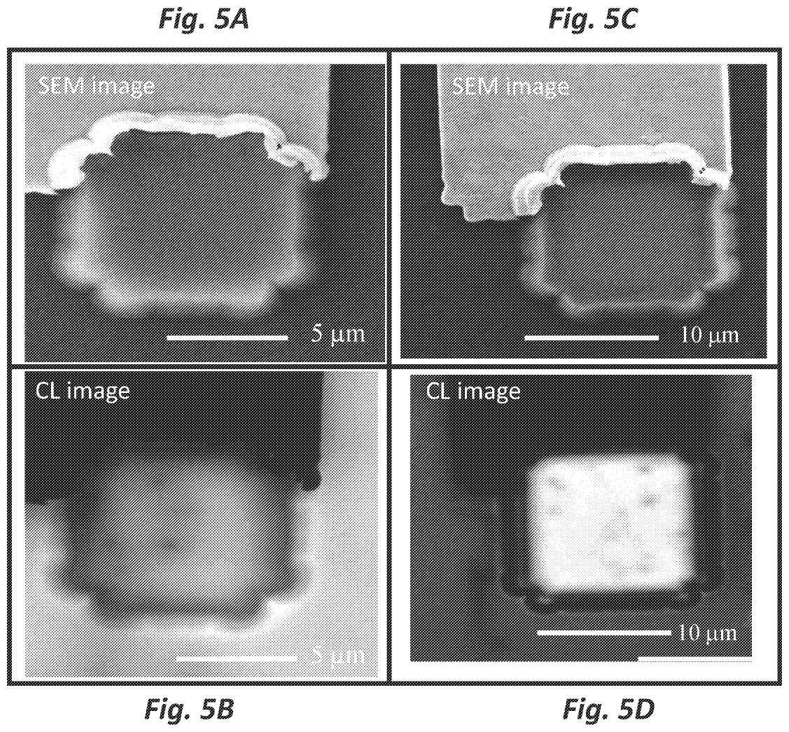

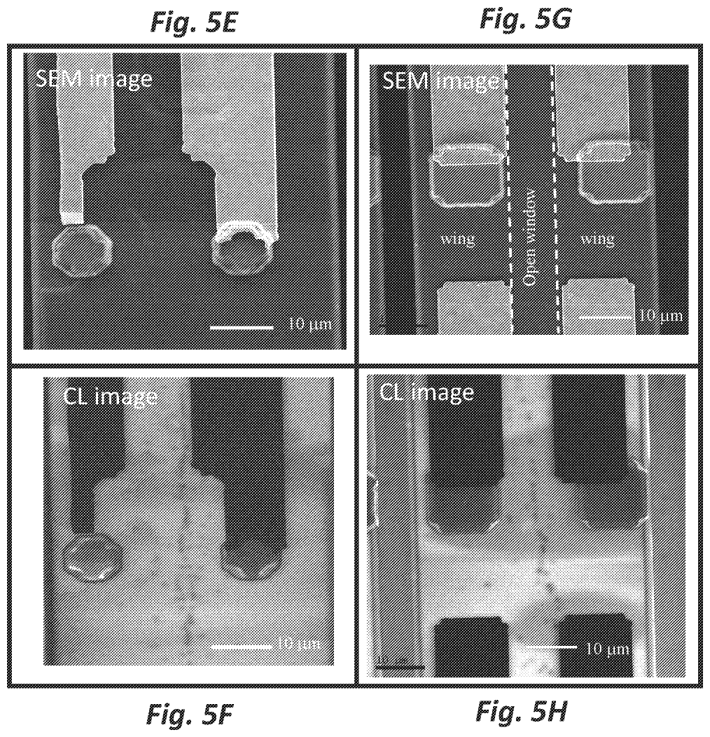

FIGS. 5A, 5B, 5C, 5D, 5E, 5F, 5G and 5H are SEM and CL images illustrating various alternatives.

FIGS. 5A and 5B are SEM and CL images, respectively, of a 10 μm×10 μm device 110 fabricated on a bulk GaN substrate 101 with a defect density of 7×10⁶ cm⁻².

FIGS. 5C and 5D are SEM and CL images, respectively, of a 15 μm×15 μm device 110 fabricated on a bulk GaN substrate 101 with a defect density of 6×10⁶ cm⁻².

FIGS. 5E and 5F are SEM and CL images, respectively, of a 10 μm×10 μm device 110 fabricated on a wing of the III-nitride ELO layers 105 with a defect density of 6-8×10⁶ cm⁻² in the region 202 and a defect density of <3×10⁵ cm⁻² on the wing of the III-nitride ELO layers 105.

FIGS. 5G and 5H are SEM and CL images, respectively, of a 15 μm×15 μm device 110 fabricated on a wing of the III-nitride ELO layers 105 with a defect density of 6˜8×10⁶ cm⁻² in the region 202 and a defect density of <3×10⁵ cm⁻² on the wing of the III-nitride ELO layers 105.

In most cases, no visual defects have been observed.

In fabricating these devices 110, after defining the light emitting mesa 302 using plasma (reactive ion) etching, a chemical treatment comprising very brief BHF dip was introduced and then a protection layer 408 comprising a 300 nm thick SiO₂ passivation layer, was deposited using sputter.

Reports indicate that, when the light emitting mesa 302 has dimensions below 100 μm×100 μm, special care must be taken, such as atomic layer deposition (ALD) of the protection layer, and the use of chemical treatments, such as KOH, to repair the plasma damage incurred by the light emitting mesa 302. The ALD deposition method is very clean and pure oxides can be formed by such chemical treatments; however, to simplify the cost model of the fabrication, simple alternatives and reduced fabrication steps are preferred.

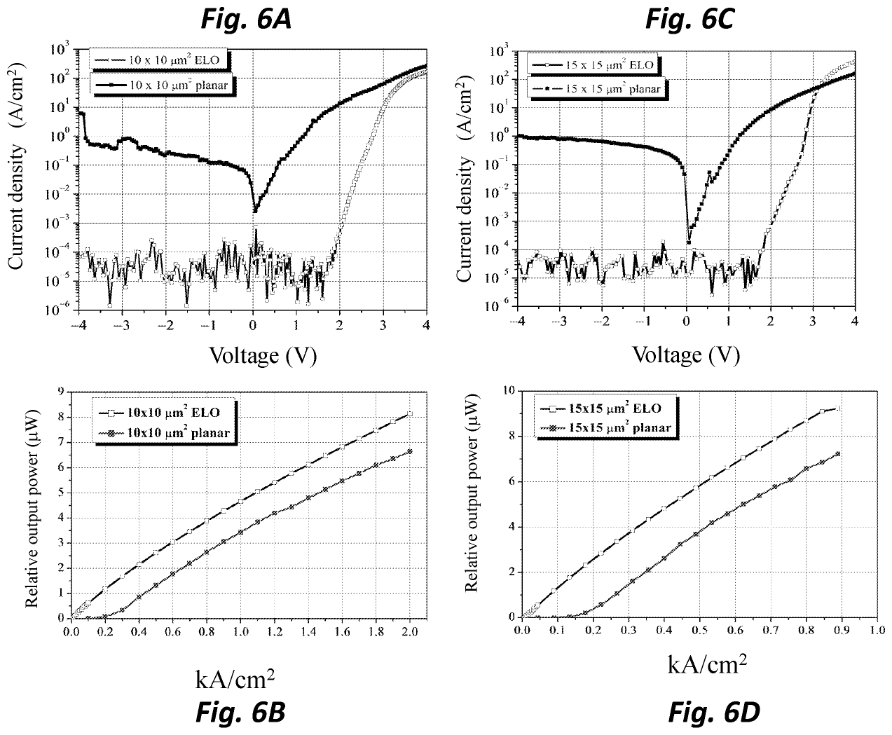

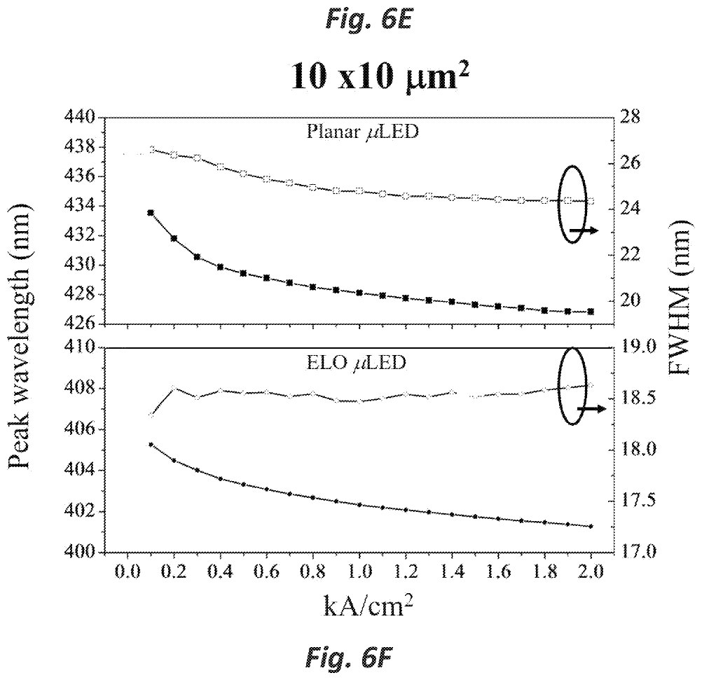

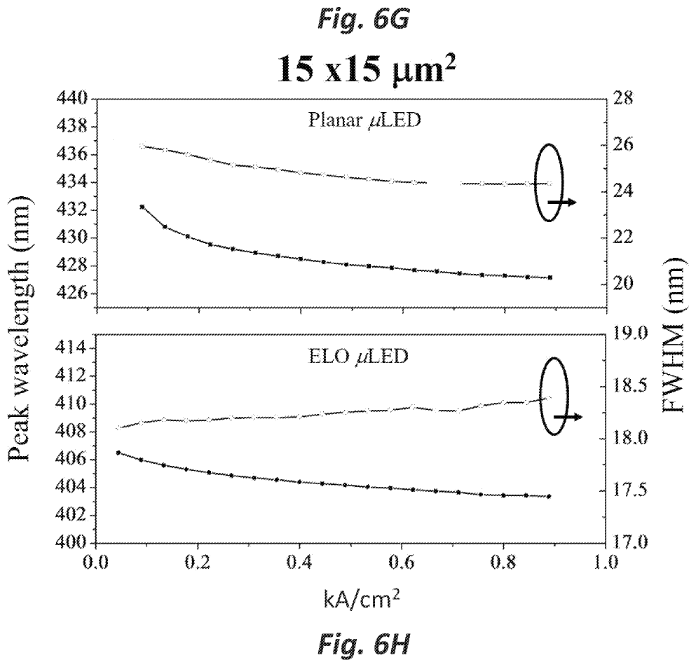

FIGS. 6A, 6B, 6C and 6D are graphs of current-voltage-optical power for devices 110 fabricated from a planar bulk GaN substrate 101 and on wings of the III-nitride ELO layers 105 grown on the same planar bulk GaN substrate 110.

FIGS. 6A and 6B are graphs of current density (A/cm²) vs. voltage (V) and relative output power (ρW) vs. current density (kA/cm²), respectively, of a 10 μm×10 μm device 110 fabricated both on wings of the III-nitride ELO layers 105 grown on the same planar bulk GaN substrate 110 (labeled as 10 μm×10 μm² ELO) and on a planar bulk GaN substrate 101 (labeled as 10 μm×10 μm² planar).

FIGS. 6C and 6D are graphs of current density (A/cm²) vs. voltage (V) and relative output power (μW) vs. current density (kA/cm²), respectively, of a 15 μm×15 μm device 110 fabricated both on wings of the III-nitride ELO layers 105 grown on the same planar bulk GaN substrate 110 (labeled as 15 μm×15 μm² ELO) and on a planar bulk GaN substrate 101 (labeled as 15 μm×15 μm² planar).

Negative voltage characteristics can be mainly seen as the measure of quality, whether a severe damage was introduced onto the light emitting mesa 302 of the device 110 or not. As can be seen, plasma etching must have damaged the sidewalls of the device 110 made on the planar bulk GaN substrate 101, which has a defect density in the order of 10⁶ cm⁻², since the simple passivation technique might have failed to recover from the damage. The leakage current is at least 4 orders of magnitude larger than the devices 110 made on the wings of the III-nitride ELO layers 105, where the leakage current is −4V. However, the device 110 fabricated on the wings of the III-nitride ELO layers 105, which has defect densities on the order of 10⁵ cm⁻² or even lower, showed a better leakage current characteristic and maintained a forward voltage of 2V, thus indicating that better quality epitaxial layers may rule out complex fabrication techniques and superior performance can be expected over devices 110 made with more defect density epitaxial layers.

FIGS. 6E, 6F, 6G and 6H are graphs of peak wavelength (nm) and FWHM (nm) of the peak wavelength vs. current density (kA/cm²) for devices 110 fabricated from a planar bulk GaN substrate 101 and on wings of the III-nitride ELO layers 105 grown on the same planar bulk GaN substrate 110.

FIGS. 6E and 6F are graphs of peak wavelength (nm) and FWHM (nm) of the peak wavelength vs. current density (kA/cm²) of a 10 μm×10 μm device 110 fabricated both on a planar bulk GaN substrate 101 (labeled as 10 μm×10 μm² planar μLED) and on wings of the III-nitride ELO layers 105 grown on the same planar bulk GaN substrate 110 (labeled as 10 μm×10 μm² ELO μLED).

FIGS. 6G and 6H are graphs of peak wavelength (nm) and FWHM (nm) of the peak wavelength vs. current density of a 15 μm×15 μm device 110 fabricated both on a planar bulk GaN substrate 101 (labeled as 15 μm×15 μm² planar μLED) and on wings of the III-nitride ELO layers 105 grown on the same planar bulk GaN substrate 110 (labeled as 15 μm×15 μm² ELO μLED).

Better crystalline quality in base layers can help reduce indium alloy composition fluctuations in subsequently grown quantum wells, which minimizes spectrum spread. FIGS. 6E, 6F, 6G and 6H illustrate that μLEDs grown using ELO have a smaller shift in peak emission wavelength and a narrower spectrum spread with increased current density. As a result, the μLEDs have an emission spectrum is that is narrower as compared to an LED using more complex designs, such as photonic crystals, resonant cavities, or other directional measures. Therefore, μLEDs grown using ELO will be a better choice for high quality display and lighting applications that require better color quality and crisp imaging from narrow spectrum light emission sources.

### Second Embodiment

A second embodiment is about the structure of electrical injection. In the first embodiment, a lateral pad configuration and electrical injection is used, as shown in FIGS. 4B and 4C. In this embodiment, however, a vertical pad configuration and electrical injection is used, wherein an interface of the III-nitride ELO layers 105 with the growth restrict mask 102 is used as one of the electrical injection pads, as shown in FIGS. 4D and 4E.

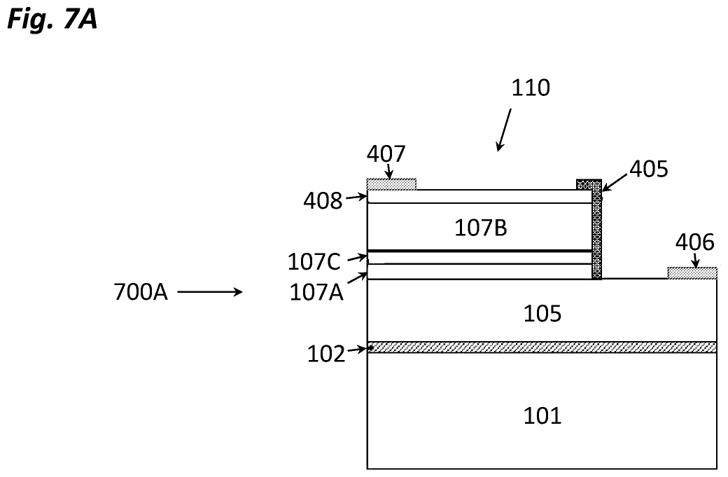

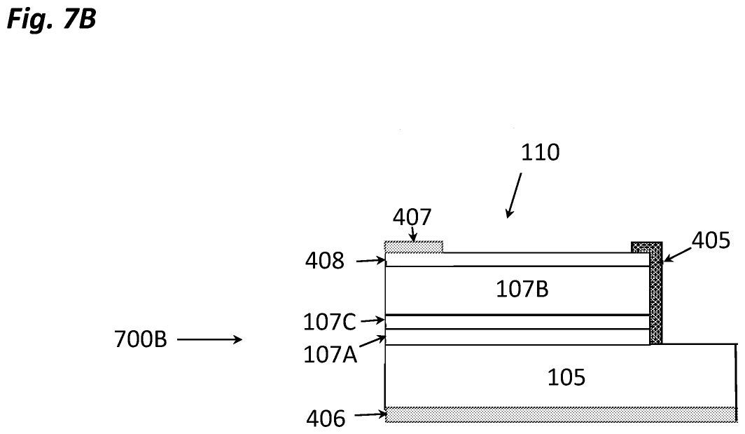

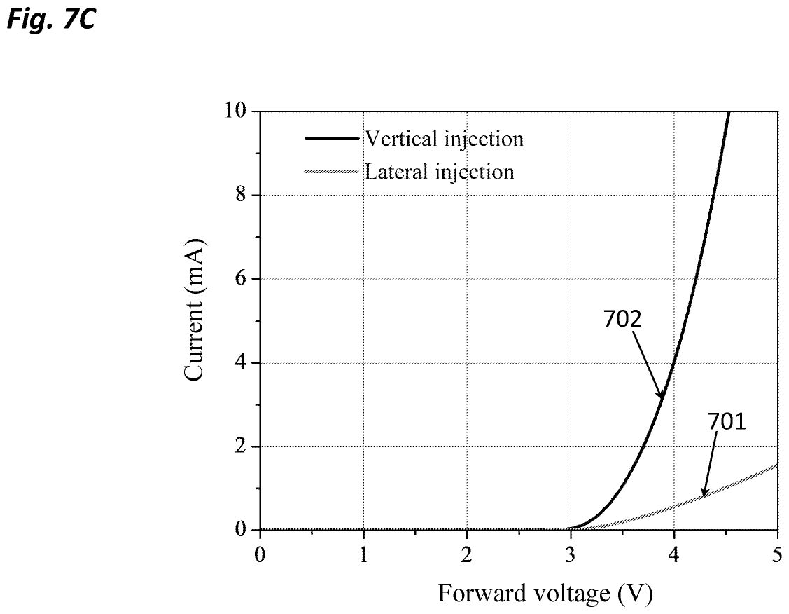

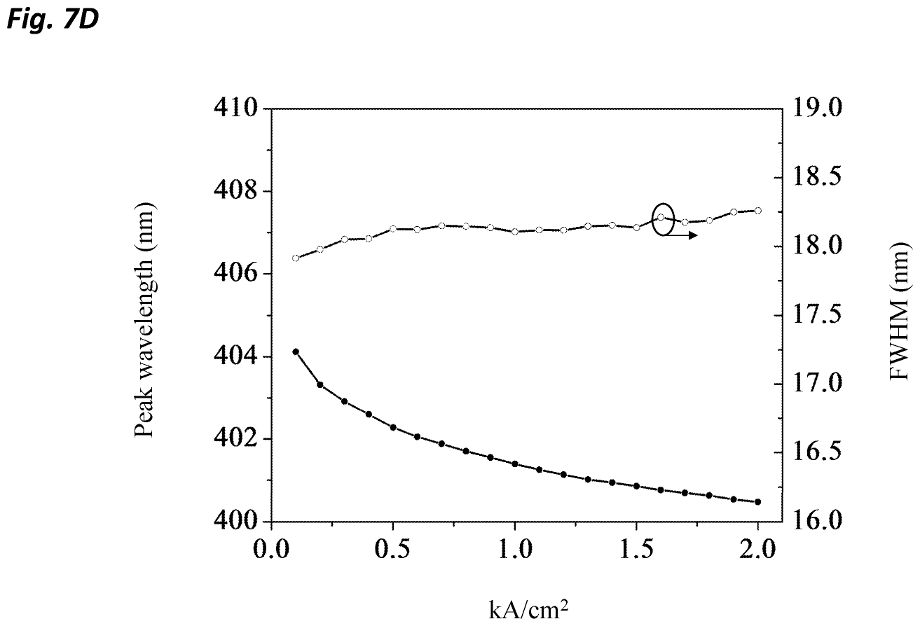

FIGS. 7A and 7B are cross-sectional schematics 700A, 700B of a lateral injection LED and a vertical injection LED, respectively.

Schematic 700A in FIG. 7A illustrates the lateral injection LED, which includes a GaN substrate 101, growth restrict mask 102, III-nitride ELO layers 105 comprised of n-GaN, an active region 107A comprised of InGaN/GaN MQW, an EBL 107C comprised of p-AlGaN, a p-type layer 107B comprised of p-GaN, a current spreading layer 408 comprised of ITO, a protective layer 405 that is an isolation layer comprised of SiO₂, an n-contact 406 comprised of Ti/Al/Ni/Au, and a p-contact 407 comprised of Ti/Au.

Schematic 700B in FIG. 7B illustrates the vertical injection LED, which includes III-nitride ELO layers 105 comprised of n-GaN (that have been removed from the substrate 101 and growth restrict mask 102), an active region 107A comprised of InGaN/GaN MQW, an EBL 107C comprised of p-AlGaN, a p-type layer 107B comprised of p-GaN, a current spreading layer 408 comprised of ITO, a protective layer 405 that is an isolation layer comprised of SiO₂, an n-contact 406 comprised of Ti/Al/Ni/Au, and a p-contact 407 comprised of Ti/Au.

FIG. 7C is a graph of current (mA) vs. forward voltage (V) of the devices 110 of FIGS. 7A and 7B, wherein curve 701 corresponds to the lateral injection device 110 of FIG. 7A and curve 702 corresponds to the vertical injection device 110 of FIG. 7B. It can be seen that the vertical injection configuration of FIG. 7B supports more current at the same bias voltages than the lateral injection configuration of FIG. 7A and thus improves the energy conversion efficiencies.

FIG. 7D is a graph of peak wavelength (nm) and FWHM (nm) of the peak wavelength vs. current density (kA/cm²) of the devices 110 of FIGS. 7A and 7B, measured after separating the devices 110 from the substrate 101. It can be seen that the peak wavelength and FWHM vs. current density were not significantly changed, indicating a damage-free liftoff for the devices 110.

### Third Embodiment

In a third embodiment, AlGaN layers are used as the island-like III-nitride semiconductor layers 105, 107. The AlGaN layers may be grown as III-nitride ELO layers 105 on various off-angle substrates 101, such as a pseudo-AlGaN substrate 101. The AlGaN ELO layers 105 can have a very smooth surface using the present invention, and the AlGaN ELO layers 105 and III-nitride device layers 107 can be removed, as the island-like III-nitride semiconductor layers 105, 107, from various off angle substrates 101. The resulting device 110 comprises a laser diode, which emits UV-light (UV-A or UV-B or UV-C). In this embodiment, one can obtain a high-quality UV-LED panel, and applications of this embodiment may lead to sterilization, lighting, etc.

### Fourth Embodiment

In a fourth embodiment, the III-nitride ELO layers 105 are grown on various off-angle substrates 101. The off-angle orientations range from 0 to +15 degrees and 0 to −28 degrees from the m-plane towards the c-plane. The present invention can remove the bar of the device 110 from the various off-angle substrates 101. This is a big advantage for this technique, as various off-angle orientations semiconductor plane devices 110 can be realized without changing the fabrication process.

### Fifth Embodiment

In a fifth embodiment, the III-nitride ELO layers 105 are grown on a c-plane substrate 101 with two different mis-cut orientations. Then, the III-nitride ELO layers 105 grown on the c-plane substrate 101 possess very less defect densities on the wings of the III-nitride ELO layers 105, where the proposed devices 110 can be made.

### Sixth Embodiment

In a sixth embodiment, a sapphire substrate 101. The resulting structure is almost the same as the first and second embodiments. In this embodiment, a buffer layer is grown first on the sapphire substrate 101, followed by an additional n-GaN layer or undoped GaN layer. The buffer layer is typically grown at a low temperature of about 500-700° C. degrees, while the n-GaN layer or undoped GaN layer is grown at a higher temperature of about 900-1200° C. degrees, with the buffer layer and n-GaN layer or undoped GaN layer having a total thickness of about 1-3 μm. Then, the growth restrict mask 102 is deposited on the buffer layer and the n-GaN layer or undoped GaN layer.

On the other hand, it is not necessary to use the buffer layer and the n-GaN layer or undoped GaN layer. For example, the growth restrict mask 102 can be disposed on the sapphire substrate 101 directly. After that, the III-nitride ELO layers 105 and/or III-nitride device layers 107 can be grown on or above the growth restrict mask 102.

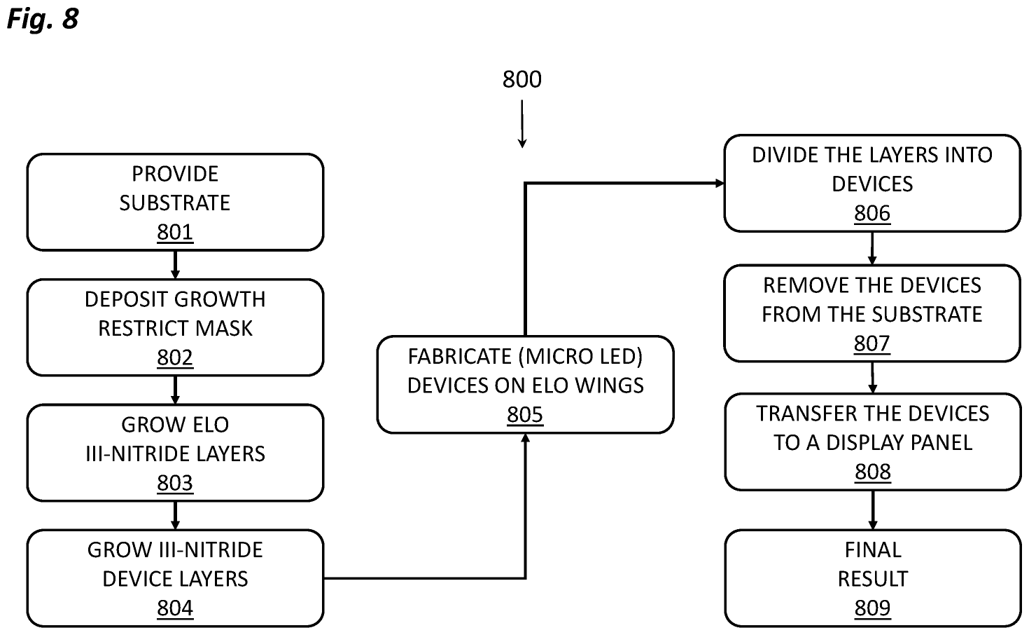

Process Steps FIG. 8 is a flowchart illustrating a method 800 for fabricating semiconducting devices according to this invention. Specifically. FIG. 8 illustrates a method 800 for fabricating small size LEDs on high-quality epitaxial crystal layers.

Block 801 represents the step of providing a substrate 101. In this step, the substrate comprises a III-nitride substrate or a foreign substrate with a III-nitride template deposited thereon.

Block 802 represents the step of forming a growth restrict mask 102 on or above the substrate 101. Specifically, the growth restrict mask 102 is deposited directly on the substrate 101, or is deposited directly on the III-nitride template deposited on the substrate 101. The growth restrict mask 102 is typically an insulator film, for example, SiO₂, SiN, SiON, TiN, etc., comprised of opening areas 103 separated by stripes of the growth restrict mask 102, and deposited, for example, by plasma chemical vapor deposition (CVD), sputter, ion beam deposition (IBD), etc., wherein the SiO₂ film is patterned by photolithography using a predetermined photomask and then etched to include the opening areas 103, as well as no-growth regions 104.

Block 803 represents the step of growing the III-nitride ELO layers 105 using ELO first from opening areas 103 in the growth restrict mask 102 and then laterally over the growth restrict mask 102, wherein the III-nitride ELO layers 105 may or may not coalesce with adjacent or neighboring III-nitride ELO layers 105.

Block 804 represents the step of growing III-nitride device layers 107 on or above the III-nitride ELO layers 105, wherein the III-nitride device layers 107 are grown on wings of the III-nitride ELO layers 105, and the III-nitride ELO layers 105 and III-nitride device layers 107 together comprise island-like III-nitride semiconductor layers 105, 107.

Block 805 represents step of fabricating small or micro-sized LED devices 110 on the island-like III-nitride semiconductor layers 105, 107.

Blocks 806 represents the step of dividing the island-like III-nitride semiconductor layers 105, 107 into separate devices 110 or groups of devices 110.

This step includes etching light emitting mesas 302 from the island-like III-nitride semiconductor layers 105, 107, wherein each of the light emitting mesas 302 corresponds to a device 110.

This step also includes etching one or more device unit patterns 301 that are each comprised of one or more of the light emitting mesas 302, for example, by etching regions 201, 202 to create the device unit patterns 301. In one example, the device unit pattern 301 is comprised of a bar formed from the island-like III-nitride semiconductor layers 105, 107, wherein the bar may be comprised of one or more devices 110.

Preferably, both the device unit pattern 301 and the light emitting mesas 302 are positioned away from a no-growth region 104 to ensure good crystal quality for the devices 110.

In addition, this step includes the step of depositing a protection layer 407, which may be a passivation layer, on sidewalls of the light emitting mesas 302, wherein a chemical treatment may be performed on the sidewalls of the light emitting mesas 302 before the protection layer 407 is deposited.

As a result, the light emitting mesas 302 have a defect density less than 3×10⁻⁶/cm² more preferably, the light emitting mesas 302 have a defect density less than 3×10⁻⁵/cm²; and most preferably, the light emitting mesas 302 have a defect density less than 3×10⁻⁴/cm².

Block 807 represents the step of removing the devices 110 from the substrate 101.

Block 808 represents the step of transferring the devices 110 onto the display panel 402 or other external carrier. Specifically, this step includes transferring the device unit patterns 301 including the island-like III-nitride semiconductor layers 105, 107 to the display panel 402 or other external carrier.

This step also includes forming a lateral injection configuration or a vertical injection configuration for injecting current into the devices 110, including depositing n- and p-contacts on the devices 110. These configurations allow each device 110 of the bar of devices 110 to be addressed separately or to be addressed together with other devices 110.

Block 809 represents the final result of the method, namely, the completed devices 110 and/or display panel 402. Preferably, the devices 110 have a size of less than 15 μm×15 μm, namely, the devices 110 are micro-sized LEDs.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method, comprising:
growing III-nitride epitaxial lateral overgrowth (ELO) layers on a substrate using a growth restrict mask, wherein the III-nitride ELO layers first grow from an opening area in the growth restrict mask and then grow laterally over the growth restrict mask;
growing III-nitride device layers on or above the III-nitride ELO layers, wherein the III-nitride device layers are grown on wings of the III-nitride ELO layers, and the III-nitride ELO layers and the III-nitride device layers together form island-like III-nitride semiconductor layers;
etching light emitting mesas from the island-like III-nitride semiconductor layers, wherein each of the light emitting mesas corresponds to a device;
etching a device unit pattern from the island-like III-nitride semiconductor layers, wherein the device unit pattern is comprised of one or more of the light emitting mesas; and
transferring the device unit pattern including the island-like III-nitride semiconductor layers to a carrier.

2. The method of claim 1, wherein the light emitting mesas have a defect density less than 3×10⁶/cm².

3. The method of claim 1, wherein the light emitting mesas have a defect density less than 3×10⁻⁵/cm².

4. The method of claim 1, wherein the light emitting mesas has a defect density less than 3×10⁻⁴/cm².

5. The method of claim 1, wherein a protection layer is deposited on sidewalls of the light emitting mesas.

6. The method of claim 1, wherein a chemical treatment is performed on the sidewalls of the light emitting mesas before the protection layer is deposited.

7. The method of claim 1, wherein the device unit pattern is comprised of a bar formed from the island-like III-nitride semiconductor layers.

8. The method of claim 7, wherein each device of the bar is addressed separately or is addressed together with other devices.

9. The method of claim 1, wherein the device unit pattern and the light emitting mesas are positioned away from a no-growth region to ensure good crystal quality for the devices.

10. The method of claim 1, wherein current is injected into the device using a lateral pad configuration.

11. The method of claim 1, wherein current is injected into the device using a vertical pad configuration.

12. The method of claim 1, wherein the device has a size of less than 15 μm×15 μm.

13. The method of claim 12, wherein the device is a micro-sized light emitting diode (LED).

14. The method of claim 13, wherein the micro-sized LED has an emission spectrum is that is narrower as compared to an LED using photonic crystals, resonant cavities, or other directional measures.

15. The method of claim 1, wherein the carrier comprises a display panel.

16. A device, comprising:
III-nitride epitaxial lateral overgrowth (ELO) layers grown on a substrate using a growth restrict mask, wherein the III-nitride ELO layers first are grown from an opening area in the growth restrict mask and then are grown laterally over the growth restrict mask;
III-nitride device layers grown on or above the III-nitride ELO layers, wherein the III-nitride device layers are grown on wings of the III-nitride ELO layers, and the III-nitride ELO layers and the III-nitride device layers together form island-like III-nitride semiconductor layers;
light emitting mesas etched from the island-like III-nitride semiconductor layers, wherein each of the light emitting mesas corresponds to a device;
a device unit pattern is etched from the island-like III-nitride semiconductor layers, wherein the device unit pattern is comprised of one or more of the light emitting mesas; and
the device unit pattern including the island-like III-nitride semiconductor layers are transferred to a carrier.
